(19) United States
(12) Patent Application Publication
(10) Pub. No.: US 2015/0368795 A1
(43) Pub. Date: Dec. 24, 2015

(54) INLET AND REACTING SYSTEM HAVING THE SAME

(71) Applicant: LG SILTRON INCORPORATED, Gyeongsangbuk-do (KR)

(72) Inventors: Man Kee CHO, Gumi-si (JP); Su Bin SON, Gumi-si (KR); Deuk Cheon RYU, Gumi-si (KR)

(21) Appl. No.: 14/767,727

(22) PCT Filed: Sep. 17, 2013
(86) PCT No.: PCT/KR2013/008395

§ 371 Date: Aug. 13, 2015

(30) Foreign Application Priority Data
Feb. 14, 2013 (KR) 10-2013-0015739

(51) Int. Cl. C23C 16/44; B01D 53/76

(52) U.S. Cl. CPC C23C 16/4407; B01D 53/76; C23C 16/4412

(57) ABSTRACT

An inlet and a reacting system having the same are disclosed. The inlet includes a body provided therein with a transport duct allowing a fluid to flow therethrough, at least one first nozzle connected to one region of a lateral surface of the body and adapted to spray a cleaning solution into the transport duct, and a blocking sheet disposed in the transport duct to be spaced apart from an inner wall of the transport duct, wherein the cleaning solution sprayed from the first nozzle is blocked from being introduced into one region of the transport duct positioned inside the blocking sheet.

### TECHNICAL FIELD

The present invention relates to an inlet of a scrubber for gas processing in a semiconductor manufacturing process and a reacting system having the same.

### BACKGROUND ART

Various kinds of reaction gases used in a semiconductor process of forming a thin film on a wafer contain oxidative components, flammable components, and harmful components. Accordingly, if a waste gas, an exhaust reaction gas, is directly emitted into the atmosphere, it may harm human bodies and pollute the environment.

A scrubber to remove harmful components from the waste gas may be installed in an exhaust line of semiconductor equipment for exhaust of waste gas. To emit the waste gas into the atmosphere through a purification process of lowering the harmful component content of the waste gas to a concentration equal to or lower than an allowable concentration, a scrubber is used, which may be one of various types of scrubbers including a burn scrubber, a burn and wet scrubber, a burn and dry scrubber, a dry scrubber, and a wet scrubber.

An inlet is needed to connect the exhaust line of the semiconductor equipment with the scrubber. The inlet [symbol] the waste gas introduced into the exhaust line and a cleaning solution to eliminate contaminants contained in the waste gas may be together introduced into the scrubber. At this time, a reaction product may be produced by reaction between the cleaning solution and contaminants. Accordingly, the inlet may be clogged by the produced reaction product.

### DISCLOSURE

### Technical Problem

An object of the present invention devised to solve the problem lies on an inlet that may extend the replacement period and reduce time for which a reacting system is stopped, contributing to increase in the amount of production, and a reacting system having the same.

### Technical Solution

The object of the present invention can be achieved by providing an inlet includes a body provided therein with a transport duct allowing a fluid to flow therethrough, at least one first nozzle connected to one region of a lateral surface of the body and adapted to spray a cleaning solution into the transport duct, and a blocking sheet disposed in the transport duct to be spaced apart from an inner wall of the transport duct, wherein the cleaning solution sprayed from the first nozzle is blocked from being introduced into one region of the transport duct positioned inside the blocking sheet.

An upper end of the blocking sheet may be positioned at an upper side of the first nozzle, and a lower end of the blocking sheet may be positioned at a lower side of the first nozzle.

The body may be provided with a fixing portion positioned at an upper side of the first nozzle in the transport duct to support an upper end of the blocking sheet.

The fixing portion may be a part of the body positioned at the upper side of the first nozzle, wherein an inner diameter of the fixing portion may be less than an inner diameter of the other part of the body.

At least one first nozzle may include a plurality of first nozzles arranged spaced apart from each other.

An angle formed between the first nozzles and an outer wall of the body positioned at an upper side of the first nozzles may be between 50° and 70°.

The blocking sheet may be formed of a resin material having a coefficient of friction less than a coefficient of friction of the body. The blocking sheet may be formed of polytetrafluoroethylene.

The blocking sheet may be provided with an upper end, a lower end, and a lateral surface positioned between the upper end and the lower end, and may be formed in a cylindrical shape and open at the upper end of the lower end.

The upper end of the blocking sheet may be formed in a ring shape having a diameter greater than a diameter of the lateral surface to be held by the fixing portion. The upper end of the blocking sheet may protrude from the lateral surface.

The inlet may further include at least one second nozzle connected to another region of the lateral surface of the body positioned under the blocking sheet and adapted to spray an inert gas into the transport duct. The at least one second nozzle may include a plurality of second nozzles arranged spaced apart from each other.

The angle formed between the second nozzles and an outer wall of the body positioned at an upper side of the second nozzles may be between 50° and 70°.

The second nozzles may spray the inert gas along an inner wall of the transport duct.

An angle formed between a direction in which the second nozzle sprays the inert gas and a normal line to an inner wall of the transport duct may be greater than 0° and less than 10°.

The inlet may further include at least one spray nozzle to spray, at a predetermined spray pressure, a gas or a liquid onto a reaction product deposited on a lower end of the blocking sheet or deposited on an inner wall of ht transport duct under the blocking sheet, wherein the reaction product may be an output according to reaction between the fluid introduced into the transport duct and the cleaning solution.

The least one first nozzle and the at least one spray nozzle may spray deionized water, the at least one spray nozzle including a plurality of spray nozzles.

A ratio of a spray pressure of the deionized water sprayed from the first nozzle to a spray pressure of the deionized water sprayed from the spray nozzle may be 1:1.5 to 3.

In another aspect of the present invention, provided herein is a reacting system including a gas introduction pipe to supply a source gas, a reactor to form a reaction product using the source gas supplied through the gas introduction pipe, a gas discharge pipe to discharge a gas produced after formation of the reaction product from the reactor, a scrubber to clean the gas discharged from the gas discharge pipe using a cleaning solution, and an inlet to connect the gas discharge pipe to the scrubber, wherein the inlet includes a body provided therein with a transport duct allowing a fluid to flow therethrough, at least one first nozzle connected to one region of a lateral surface of the body and adapted to spray the cleaning solution into the transport duct, and a blocking sheet disposed in the transport duct to be spaced apart from an inner wall of the transport duct, wherein the cleaning solution sprayed from the first nozzle is blocked from being introduced into one region of the transport duct positioned inside the blocking sheet.

### Advantageous Effects

According to one embodiment, a replacement period may be extended, and the time for which the reacting system is stopped for replacement of the inlet may be reduced. Thereby, the amount of production may increase.

### DESCRIPTION OF DRAWINGS

The accompanying drawings, which are included to provide a further understanding of the invention, illustrate embodiments of the invention and together with the description serve to explain the principle of the invention.

In the drawings:

FIG. 1 illustrates a reacting system including a scrubber equipped with an inlet according to an exemplary embodiment and a reactor;

FIG. 2 is a front view showing an inlet according to a first embodiment;

FIG. 3 is a cross-sectional view illustrating the inlet shown in FIG. 2;

FIG. 4 illustrates a blocking sheet shown in FIG. 3;

FIG. 5 is a conceptual view illustrating the function of the blocking sheet shown in FIG. 3;

FIG. 6A illustrates formation of a reaction product in the cast that the blocking sheet is not provided;

FIG. 6B illustrates formation of a reaction product in the cast that the blocking sheet is provided.

FIG. 7 is a front view illustrating an inlet according to a second embodiment;

FIG. 8 is a cross-sectional view illustrating the inlet shown in FIG. 7;

FIG. 9 is a conceptual view illustrating the function of a second nozzle shown in FIG. 8;

FIG. 10 is a view illustrating the spray direction of the second nozzle shown in FIG. 8;

FIGS. 11A and 11B illustrate a spray direction of the second nozzles according to one embodiment;

FIG. 12 is a front view illustrating an inlet according to a third embodiment;

FIG. 13 is a cross-sectional view illustrating the inlet shown in FIG. 12;

FIG. 14 illustrates disposition of spray nozzles of the inlet shown in FIG. 12; and

FIG. 15 is a conceptual view illustrating the function of the spray nozzles shown in FIG. 13.

### BEST MODE

Reference will now be made in detail to the preferred embodiments of the present invention, examples of which are illustrated in the accompanying drawings. In the disclosure of embodiments, when a layer (film), a region, a pattern, or a structure is described as being formed “on” or “under” a substrate, a layer (a film), a region, a pad, or a pattern, the terms “on” and “under” connote not only “directly on” and “directly under” but also “indirectly on” and “directly under” with an interposed layer. In addition, the concepts of “on” and “under” are defined with reference to the drawings.

Regarding the sizes of constituents shown in the drawings, the constituents are exaggerated, omitted, or schematically shown for clear and easy description. In addition, the size of each constituent does not fully reflect the real size. Wherever possible, the same reference numbers will be used throughout the drawings to refer to the same or like parts. Hereinafter, a scrubber and an inlet according to embodiments will be described with reference to the accompanying drawings.

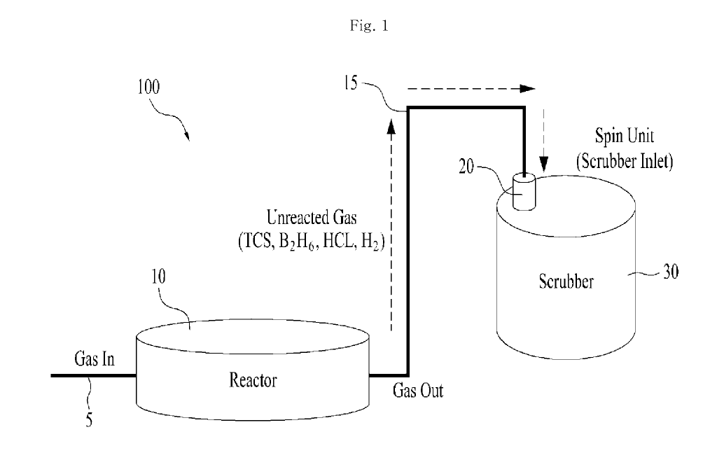

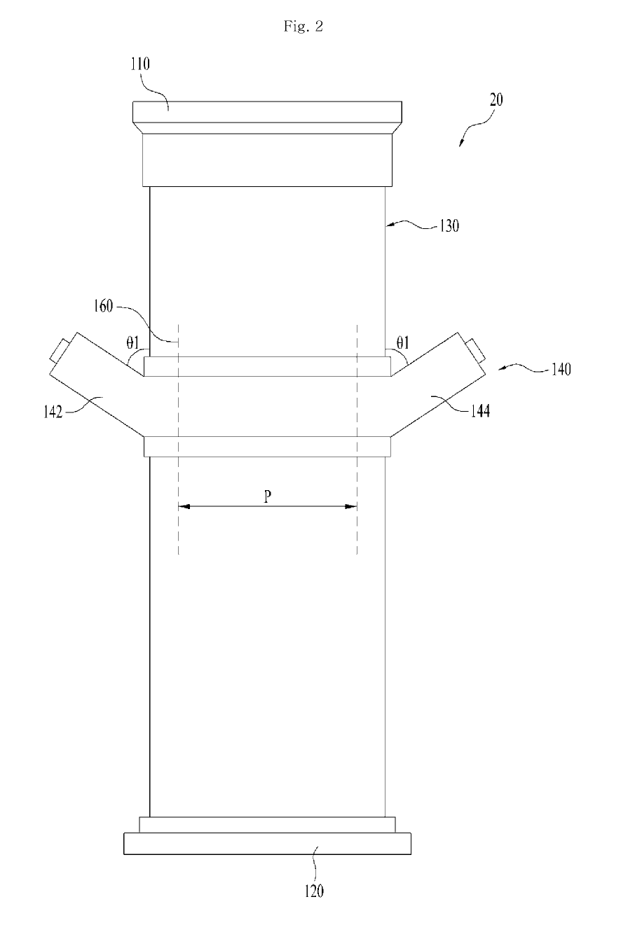

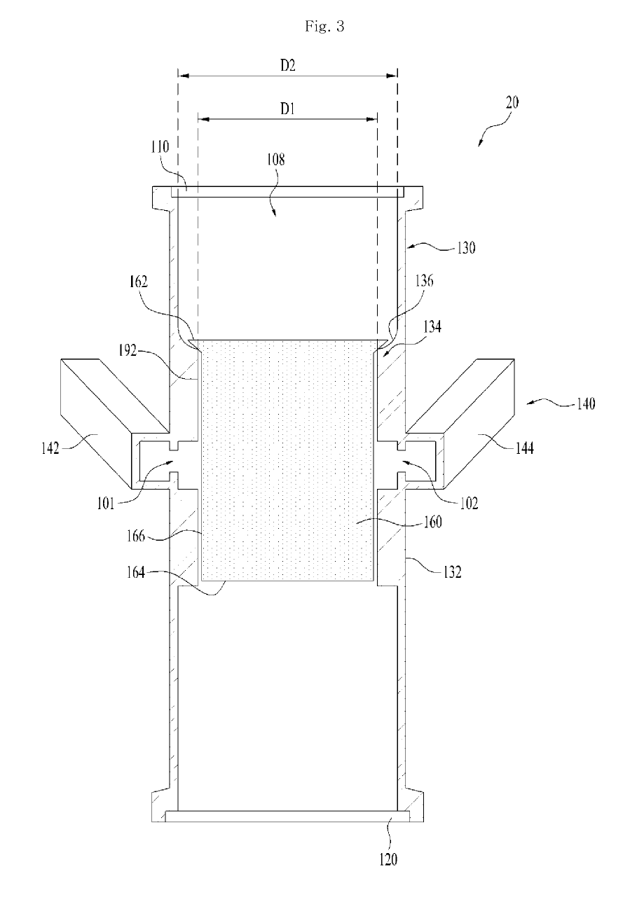

FIG. 1 illustrates a reacting system 100 including a scrubber 30 equipped with an inlet 20 according to an exemplary embodiment and a reactor 10, and FIG. 2 is a front view showing the inlet 20 according to a first embodiment. FIG. 3 is a cross-sectional view illustrating the inlet 20 shown in FIG. 2. The reacting system 100 may be an epitaxial reacting apparatus. However, embodiments are not limited thereto.

Referring to FIGS. 1 to 3, the reacting system 100 may include a gas introduction pipe 5, a reactor 10, a gas discharge pipe 15, an inlet 20, and a scrubber 30.

The gas introduction pipe 5 is connected to the reactor 10 to provide various source gases to the reactor 10.

The reactor 10 may perform a specific reaction using a source gas supplied through the gas introduction pipe 5, and may form a reaction product as a result of the reaction. For example, the reactor 10 may form a thin film on a wafer through an epitaxial reaction.

The gas discharge pipe 15 may be connected to the reactor 10. A gas produced after formation of a reaction product may be discharged from the reactor 10 through the gas discharge pipe 15. Herein, the gasses discharged through the gas discharge pipe 15 may be unreacted gases (e.g., TCS, B2H6, HCL and H2) and contaminants.

The inlet 20 may connect the gas discharge pipe 15 to the scrubber 30, functioning as a passage through which unreacted gases and contaminants discharged through the gas discharge pipe 15 move to the scrubber 30.

When the inlet 20 is clogged by the reaction product, unreacted gases and contaminants cannot move to the scrubber 30. In this case, the inlet 30 needs to be removed to eliminate the reaction product or to be replaced with a new one.

The scrubber 30 is capable of cleaning the unreacted gases and gaseous contaminants discharged from the gas discharge pipe 15 using a cleaning solution.

The contaminants introduced into the scrubber 30 may closely contact the cleaning solution stored in the scrubber 30 to dissolve in the cleaning solution, or to react with a reagent diffused through the cleaning solution to be neutralized.

The inlet 20 includes an introduction portion 110, a discharge portion 120, a body 130, a first nozzle 140, and a blocking sheet 160.

The introduction portion 110 may be connected to one end of the body 130 and provided with a hollow inner space to allow a fluid to be introduced thereinto.

The discharge portion 120 may be connected to the other end of the body 130 and provided with a hollow inner space to allow a fluid to be discharged therethrough. For example, the introduction portion 110, the body 130 and the discharge portion 120 may be integrated with each other. However, embodiments are not limited thereto.

The body 130 may include a transport duct 108 allowing a fluid to pass therethrough.

For example, the body 130 may include a transport duct 108 formed in the shape of a hollow cylindrical pipe allowing a fluid to pass therethrough.

The body 130 may be formed of a plastic material, for example, polyvinyl chloride (PVC). However, embodiments are not limited thereto.

The first nozzle 140 is connected to one region of the lateral surface 132 of the body 130, thereby spraying the cleaning solution, e.g., deionized water into the transport duct 108 of the body 130.

Openings 101 and 102 are provided in one region of the lateral surface 132 of the body 130. The first nozzle 140 may be connected to the openings 101 and 102. Thereby, the first nozzle 140 may spray the cleaning solution into the transport duct 108 of the body 130 through the openings 101 and 102.

At least one first nozzle 140 and at least one opening 101, 102 may be provided. FIGS. 2 and 3 show an embodiment provided with two first nozzles 140 and two openings 101 and 102. However, embodiments are not limited thereto. A plurality of first nozzles 142 and 144 may be arranged spaced apart from each other.

For example, the nozzle 142 may be spaced 180° apart from the nozzle 144.

The nozzle 142 may be connected to a first opening 101. Thereby, the nozzle 142 may spray the cleaning solution into the transport duct 108 of the body 130 through the first opening 101. The nozzle 144 may be connected to a second opening 102. Thereby, the nozzle 144 may spray the cleaning solution into the transport duct 108 of the body 130 through the second opening 102.

The blocking sheet 160 may be disposed in the transport duct 108 of the body 130 such that one end 162 thereof is positioned at the upper side of the first nozzle 140, and the other end 164 thereof is positioned at the lower side of the first nozzle 140.

For example, one end of the blocking sheet 160 may be the upper end of the blocking sheet 160, and the other end of the blocking sheet 160 may be the lower end of the blocking sheet 160. The blocking sheet 160 may be disposed in the transport duct 108 to be spaced apart from an inner wall 192 of the transport duct 108 of the body 130.

The first nozzle 140 may be disposed between one end 162 of the blocking sheet 160 and the other end thereof, and may spray the cleaning solution toward the lateral surface 166 of the blocking sheet 160.

The body 130 may include a fixing portion 134 positioned, at the upper side of the first nozzle 140, in the transport duct 108 to support and fix the one end 162 of the blocking sheet 160.

For example, the fixing portion 134 may be one region of the body 130 positioned at the upper side of the first nozzle 140. The inner diameter D1 of the fixing portion 134 may be smaller than the inner diameter D2 of the other portion of the body 130. The blocking sheet 160 may be fixed by the fixing portion 134, and thus may be prevented from being separated downward from the transport duct 108 of the body 130.

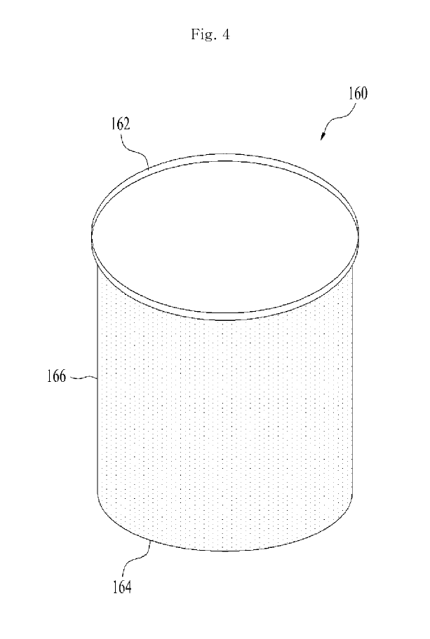

FIG. 4 illustrates the blocking sheet 160 shown in FIG. 3.

Referring to FIG. 4, the shape of the blocking sheet 160 may be determined according to the shape of the transport duct 108 of the body 130.

The blocking sheet 160 shown in FIG. 3 includes an upper end 162, a lower end 164, and a lateral surface 166 positioned between the upper end 162 and the lower end 164. The blocking sheet 160 is cylindrically formed and is open at the upper end 162 and the lower end 164. However, embodiments are not limited thereto.

The one end 162 of the blocking sheet 160 may be formed in a ring shape having a larger diameter than the lateral surface 166 to be held by the fixing portion 134. For example, the one end 162 of the blocking sheet 160 may be formed to protrude from the lateral surface 166.

The blocking sheet 160 may be formed of a resin material having a coefficient of friction less than that of the body 130, for example, polytetrafluoroethylene. However, embodiments are not limited thereto.

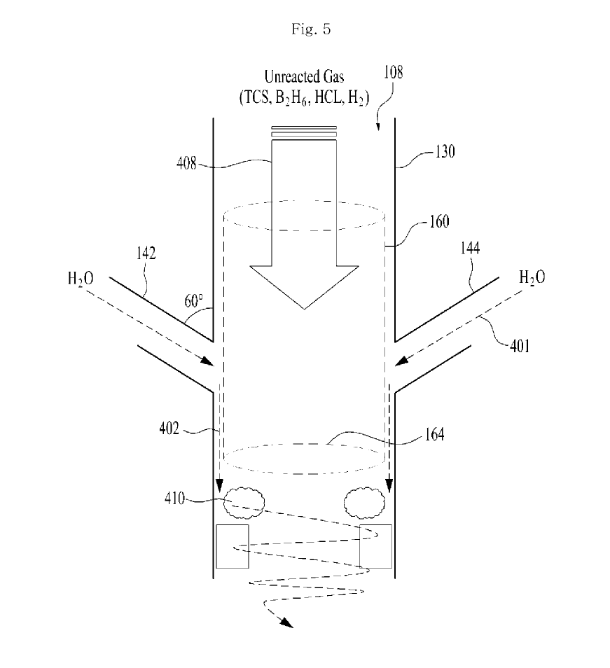

FIG. 5 is a conceptual view illustrating the function of the blocking sheet 160 shown in FIG. 3.

Referring to FIG. 5, at least one portion of the lateral surface 166 of the blocking sheet 160 may be adjacent to the openings 101 and 102.

The blocking sheet 160 blocks the cleaning solution sprayed from the first nozzles 142 and 144 from being introduced into one region P of the transport duct 108 positioned inside the blocking sheet 160. Thereby, the fluids positioned inside the blocking sheet 160, for example, unreacted gases 408 may be prevented from directly contacting and reacting with the cleaning solution.

For example, the cleaning solution 401 sprayed from the first nozzles 142 and 144 may be blocked from being supplied to the interior of the blocking sheet 160, by the outer wall of the blocking sheet 160 that the cleaning solution 401 hit. In addition, the cleaning solution 402 hitting the blocking sheet 160 may move down the lower portions of the first nozzles 142 and 144 along the inner wall 192 of the transport duct 108 or the outer wall of the blocking sheet 160.

Reaction between the cleaning solution sprayed from the first nozzles 142 and 144 and the unreacted gases 408 introduced into the transport duct 108 is prevented from occurring at an inner portion of the transport duct 108 adjacent to the first nozzles 142 and 144, by the blocking sheet 160. Thereby, a reaction product is not produced. In addition, the cleaning solution 402 moving down the blocking sheet 160 may react with the unreacted gases in a portion of the transport duct 108 under the lower end 164 of blocking sheet 160, producing a reaction product 410.

To allow the cleaning solution sprayed into the transport duct 108 to smoothly flow down along the transport duct 108, the first nozzles 142 and 144 may be inclined at a certain angle.

The angle that the first nozzles 142 and 144 make with a portion of the outer wall of the body 130 positioned at the upper side of the first nozzles 142 and 144 may be between 50° and 70°.

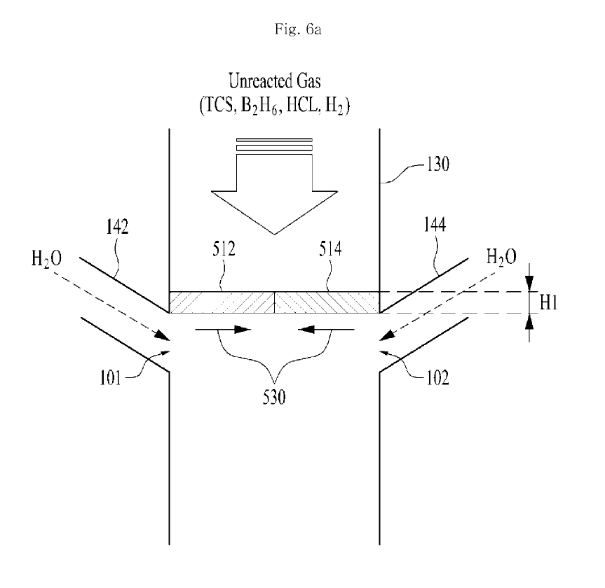

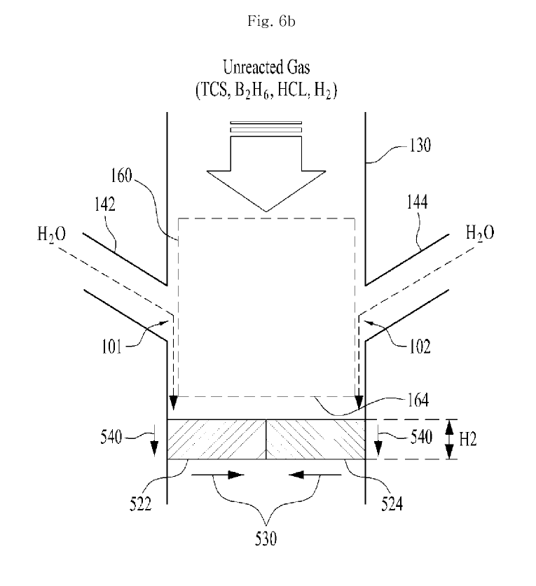

FIG. 6A illustrates formation of a reaction product in the cast that the blocking sheet is not provided, and FIG. 6B illustrates formation of a reaction product in the cast that the blocking sheet 160 is provided.

Referring to FIG. 6A, the blocking sheet is not present, and accordingly reaction between the cleaning solution and the unreacted gases may actively take place at the inside of the transport duct 108 adjacent to the openings 101 and 102 of the first nozzles 142 and 144 from which the cleaning solution is sprayed. Thereby, reaction products 512 and 514 may be deposited on the inner wall of the transport duct 108 positioned at the upper side of the openings 101 and 102.

According to Formula 1, powdered SiO2 having high adhesiveness and high flammability may be produced as the reaction products 512 and 514.

TCS(HSiCl₃)+H₂O [symbol] SiO₂+H₂+3Cl⁻ [Formula 1]

The reaction products 512 and 514 may grow on the inner wall 192 of the transport duct 108 positioned at the upper side of the first nozzles 142 and 144 and functioning as a growth interface. Due to the cleaning solution sprayed from the first nozzles 142 and 144, the growth of the reaction product in a longitudinal direction may be limited. Accordingly, the growth of the reaction products 512 and 514 mainly occurs in a lateral direction 530. As the reaction product keeps growing in the lateral direction 530, the inner space of the transport duct 108 may be gradually narrowed, and ultimately the inlet may be clogged.

If the inlet is clogged, the amount of gases used in the reacting system 100 may increase, and the temperature may drastically drop. In addition, the pressure in the reacting system 100 may increase.

Referring to FIG. 6B, due to the blocking sheet 160, reaction between the cleaning solution and unreacted gases may not take place at the inside of the transport duct 108 adjacent to the openings 101 and 102 of the first nozzles 142 and 144, and reaction products 522 and 524 may be produced under the lower end 164 of the blocking sheet 160.

That is, the location at which the reaction products are produced may be shifted from a position around the first nozzles 142 and 144 to the lower end of the blocking sheet 160 or the inner wall of the transport duct 108 positioned under the blocking sheet 160 due to the blocking sheet 160.

The reaction products 522 and 524 may grow on the growth interface. In this case, the inner wall 192 of the transport duct 108 positioned under the blocking sheet 160, or the lower end 164 of the blocking sheet 160 is the growth interface.

Since the surface of the blocking sheet 160 formed of polytetrafluoroethylene is slipperier than the inner wall 192 of the transport duct 108 formed of PVC the blocking sheet 160, growth of the reaction products on the lateral surface of the blocking sheet 160 taken as the growth interface may be suppressed.

Since the lower end 164 of the blocking sheet 160 is positioned under the first nozzles 142 and 144, growth of the reaction products 522 and 524 in the longitudinal direction is not suppressed. Accordingly, the reaction products 522 and 524 may uniformly grow in the lateral direction 530 and the longitudinal direction 540.

The thickness H2 of the reaction products 522 and 524 shown in FIG. 6B may be greater than the thickness H1 of the reaction products 512 and 514 shown in FIG. 6A. Thereby, the time taken for the inlet 20 shown in FIG. 6B to be clogged by the reaction products 522 and 524 may be longer than the time taken for the inlet 20 shown in FIG. 6A to be clogged by the reaction products 512 and 514.

In this embodiment, by providing the blocking sheet 160, the replacement period of the inlet clogged by the reaction products may be extended, and the time taken for the reacting system to be stopped for replacement of the inlet may be reduced. Thereby, the amount of production may increase.

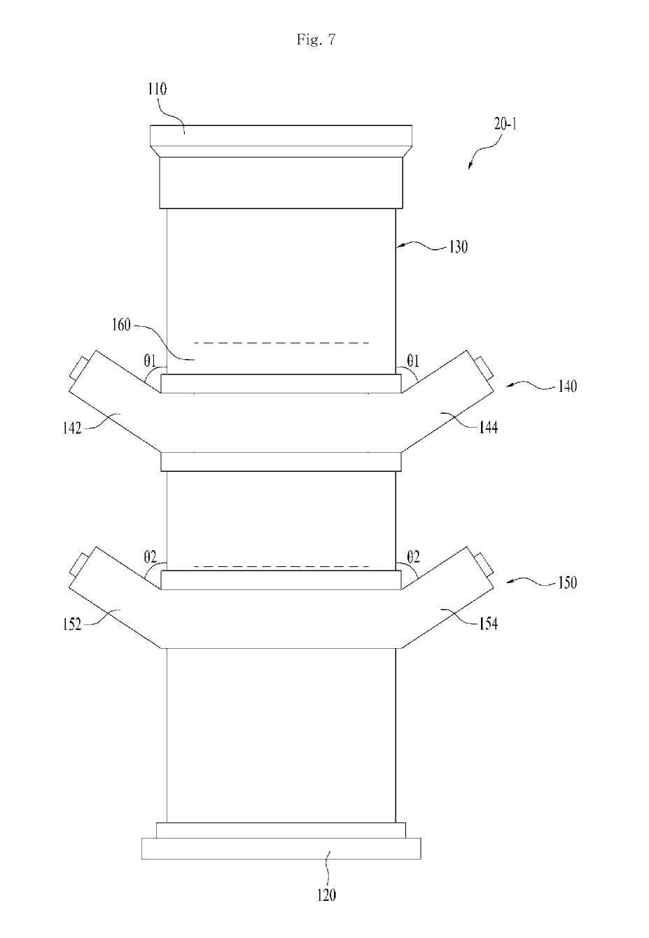

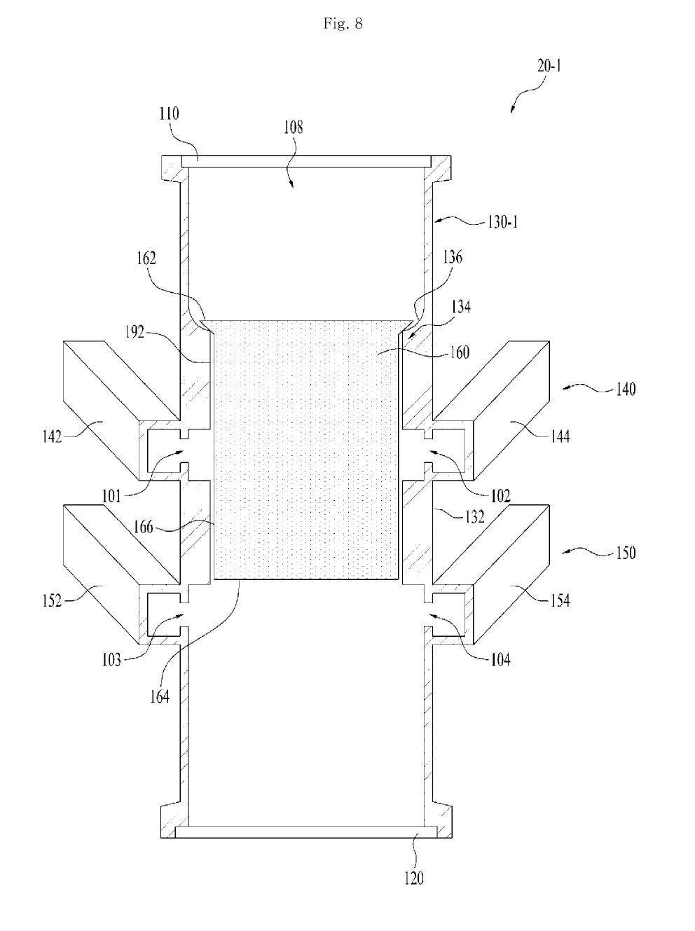

FIG. 7 is a front view illustrating an inlet 20-1 according to a second embodiment, and FIG. 8 is a cross-sectional view illustrating the inlet 20-1 shown in FIG. 7. The same reference numbers as used in FIGS. 2 and 3 represent the same constituents, a description of which will be omitted.

Compared to the inlet 20 shown in FIGS. 2 and 3, the inlet 20-1 shown in FIGS. 7 and 8 further includes a second nozzle 150.

The second nozzle 150 is connected to another region of the lateral surface 132 of the body 130 positioned under the lower end 164 of the blocking sheet 160. The second nozzle 150 may spray an inner gas such as, for example, Ar, Ne, He, N₂ and CO₂ into the transport duct 108.

At least one second nozzle 150 may be provided. FIG. 7 and FIG. 8 illustrate an embodiment provided with two second nozzles 150. However, embodiments are not limited thereto. A plurality of second nozzles 152 and 154 may be arranged spaced apart from each other.

For example, in the case that two second nozzles 150 are provided, the nozzle 152 may be spaced 180° apart from the nozzle 154.

The openings 103 and 104 may be provided in another region of the lateral surface 132 of the body 130-1 positioned under the first opening 101 and the second opening 102. The second nozzle 150 may be connected to the openings 103 and 104. Thereby, the second nozzle 150 may spray an inert gas toward the inner wall 192 of the transport duct 108 through the openings 103 and 104.

For example, the second nozzle 152 may be connected to the third opening 103. Thereby, the second nozzle 152 may spray an inert gas toward the inner wall 192 of the transport duct 108 through the third opening 103. In addition, the second nozzle 154 may be connected to a fourth opening 104. Thereby, the second nozzle 154 may spray an inert gas toward the inner wall 192 of the transport duct 108 through the fourth opening 104.

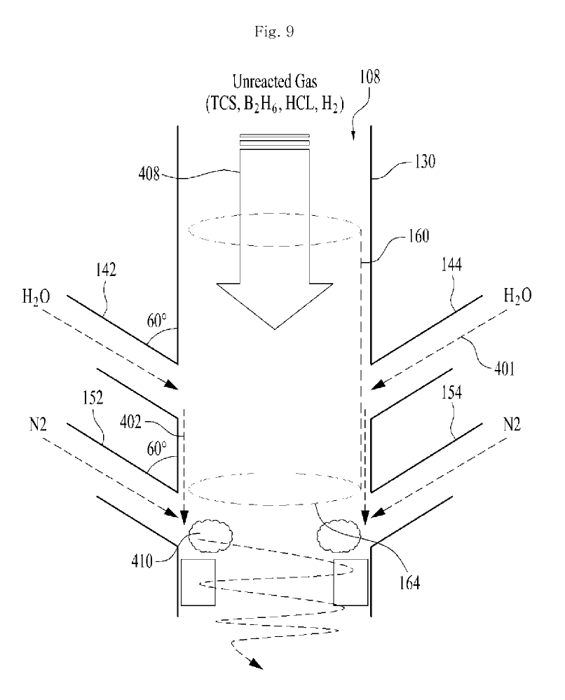

FIG. 9 is a conceptual view illustrating the function of the second nozzle 150 shown in FIG. 8.

Referring to FIG. 9, to suppress deposition of the reaction product 410 on the inner wall 192 of the transport duct 108 positioned under the blocking sheet 160, the second nozzles 152 and 154 may be inclined at a certain angle.

For example, the angle that the second nozzles 152 and 154 make with the outer wall of the body 130 positioned on the second nozzles 152 and 154 may be between 50° and 70°.

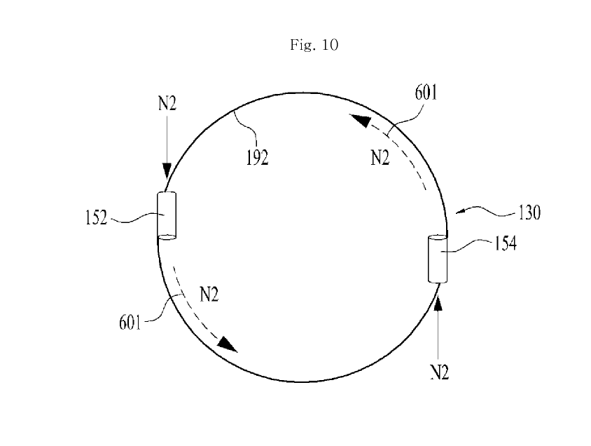

FIG. 10 is a view illustrating the spray direction of the second nozzle 150 shown in FIG. 8. Referring to FIG. 10, the second nozzle 150 does not spray an inert gas toward the center of the transport duct 108. Rather, the second nozzle 150 may spray the inert gas 601 along the inner wall 192 of the transport duct 108 positioned under the blocking sheet 160.

The second nozzles 152 and 154 may spray the inert gas 601 along the inner wall of the transport duct 108 in the same direction. For example, the second nozzles 152 and 154 may spray the inert gas 601 such that the inert gas 601 flows clockwise along the inner wall 192 of the transport duct 108.

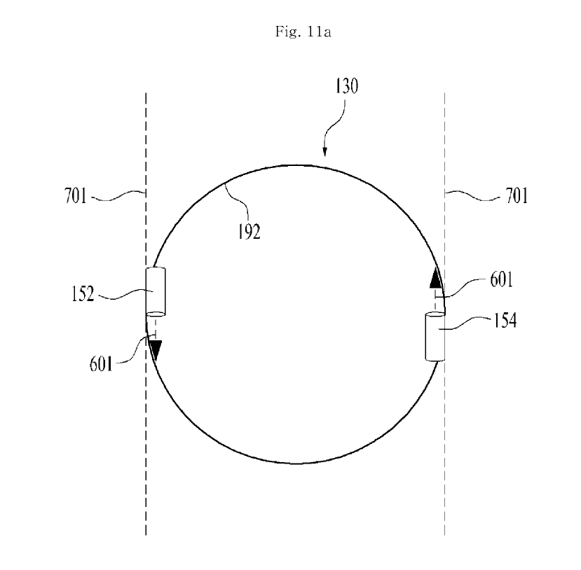

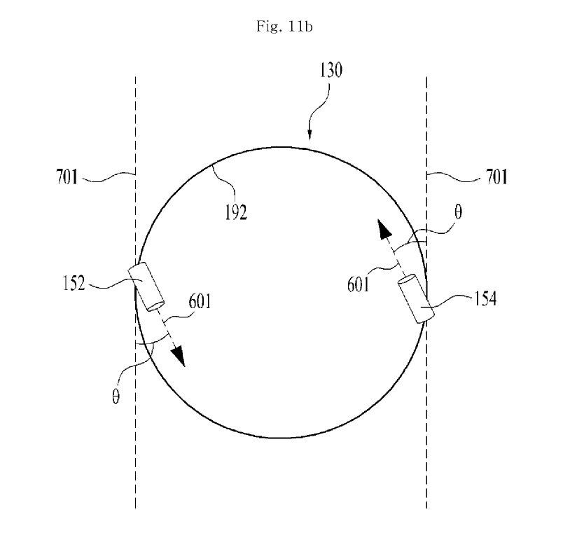

FIGS. 11A and 11B illustrate a spray direction of the second nozzles 152 and 154 according to one embodiment. Referring to FIG. 11A, the spay direction of the second nozzles 152 and 154 may be parallel with the normal line 701 to the inner wall 192 of the transport duct 108 adjacent to the second nozzle 150 and the openings 103 and 104.

Referring to FIG. 11B, the spray direction of the second nozzle 154 may make a certain angle (e.g., 0≦θ≦10°) with the normal line 701 to the inner wall 192 of the transport duct 108 adjacent to the second nozzle 150 and the openings 103 and 104.

The inert gas 601 sprayed from the second nozzle 150 and flowing along the inner wall 192 of the transport duct 108 positioned under the blocking sheet 160 may suppress deposition of the reaction product 410 on the inner wall 192 of the transport duct 108.

As the second embodiment is provided with the second nozzle 150, deposition of the reaction product 410 on the inner wall 192 of the transport duct 108 may be suppressed. Accordingly, in the second embodiment, the replacement period of the inlet may be further extended, and the time for which the reacting system is stopped for replacement of the inlet may be further reduced, compared to the first embodiment. Thereby, the amount of production may further increase.

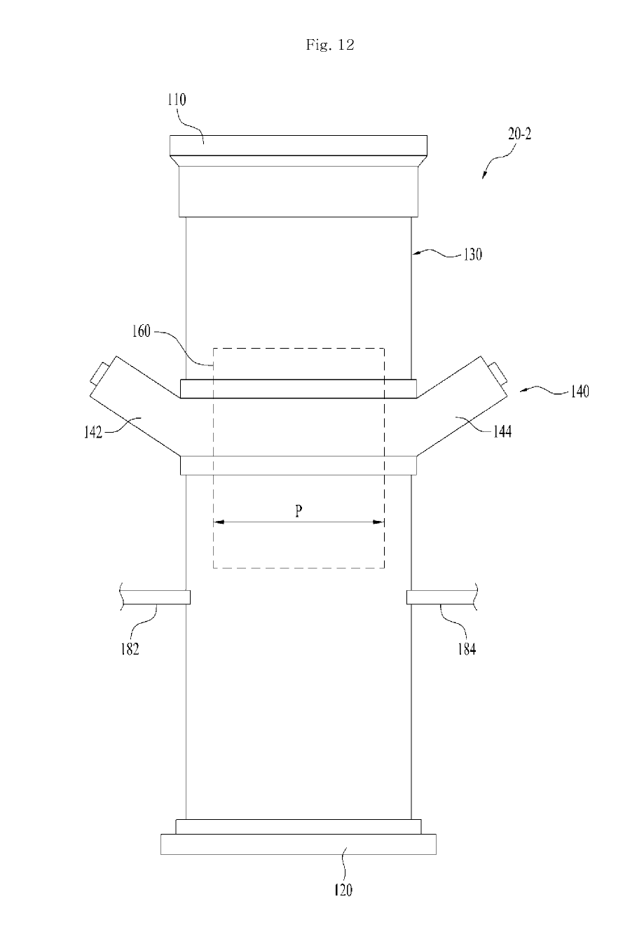

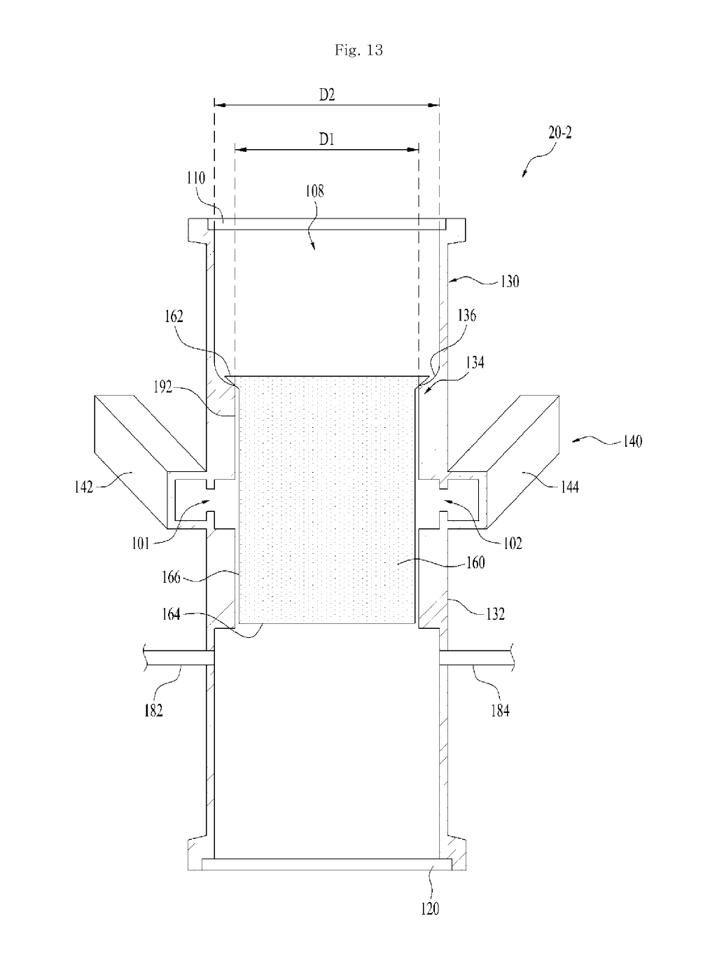

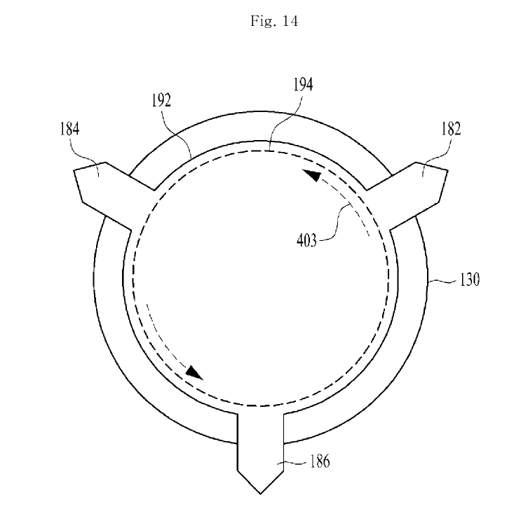

FIG. 12 is a front view illustrating an inlet 20-2 according to a third embodiment, and FIG. 13 is a cross-sectional view illustrating the inlet 20-2 shown in FIG. 12. FIG. 14 illustrates disposition of spray nozzles 182, 184 and 186 of the inlet 20-2 shown in FIG. 12. The same reference numbers as use in FIGS. 2 and 3 represent the same constituents, and accordingly a description thereof will be briefly given or omitted.

Referring to FIGS. 12 to 14, the inlet 20-2 may include an introduction portion 110, a discharge portion 120, a body 130, a first nozzle 140, a blocking sheet 160, and spray nozzles 182, 184 and 186.

The spray nozzles 182, 184 and 186 may be other regions of the lateral surface 132 of the body 130, and may spay a high-pressure liquid, for example, deionized water, or a gas, for example, air into a portion of the transport duct 108 positioned under the lower end 164 of the blocking sheet 160. Herein, the spray nozzles 182, 184 and 186 may be positioned under the lower end 164 of the blocking sheet 160.

The spray nozzles 182, 184 and 186 may spray a high-pressure liquid or gas onto reaction products deposited on the sidewall 192 of the transport duct 108 at the lower end 164 of the blocking sheet 160 to separate the reaction products from the sidewall 192 of the transport duct 108 or dissolve the reaction product.

In addition, the spray nozzles 182, 184 and 186 may spray a high-pressure liquid or gas onto reaction products deposited on the lower end 164 of the blocking sheet 160. The spray nozzles 182, 184 and 186 may spray a predetermined liquid or gas on the reaction products deposited on the lower end 164 of the blocking sheet 160 to separate the reaction products from the lower end 164 of the blocking sheet 160 or dissolve the reaction products. In this case, compared to the case shown in FIGS. 12 to 13, the spray nozzles 182, 184 and 186 may be positioned on the same level as the lower end 164 of the blocking sheet 160.

In addition, the spray nozzles 182, 184 and 186 may spray a high-pressure liquid or gas onto the lateral surface 166 of the blocking sheet 160. By spraying a high-pressure liquid or gas onto the lateral surface 166 of the blocking sheet 160, the spray nozzles 182, 184 and 186 may vibrate the blocking sheet 160. The reaction products deposited at the lower end 164 of the blocking sheet 160 may be separated from the blocking sheet 160 by vibration of the blocking sheet 160. In this case, compared to the case shown in FIGS. 12 and 13, the spray nozzles 182, 184 and 186 may be positioned on the lower end 164 of the blocking sheet 160.

The distance from the blocking sheet 160 to the spray nozzles 182, 184 and 186 may be between 2 mm and 5 mm. In the case that the distance from the blocking sheet 160 to the spray nozzles 182, 184 and 186 is less than 2 mm, water vapor may be produced and thereby reaction products may be easily deposited on the blocking sheet 160. In the case that the distance is greater than 5 mm, the spray pressure required for separation or dissolution of the reaction products may increase.

To separate the reaction products from the sidewall 192 of the transport duct 108 or the lower end 164 of the blocking sheet 160 and dissolve the reaction products, the spray pressure of the deionized water sprayed from the spray nozzles 182, 184 and 186 may be set to be higher than the spray pressure of the deionized water sprayed from the first nozzle 140.

For example, the ratio of the spray pressure of the deionized water sprayed from the first nozzle 140 to the spray pressure of the deionized water sprayed from the spray nozzles 182, 184 and 186 may be 1:1.5-3.

At least one spray nozzle 182, 184, 186 may be provided. A plurality of spray nozzles 182, 184 and 186 may be arranged spaced apart from each other.

In FIG. 14, three spray nozzles 182, 184 and 186 are spaced 120° apart from each other. However, embodiments are not limited thereto.

By the deionized water sprayed from the first nozzle 140, a water wall 194 rotating in a certain direction 403 along the inner wall 192 of the transport duct 108 may be formed. Each of the spray nozzles 182, 184 and 186 may not protrude from the inner wall 192 of the transport duct 108. This is intended to prevent one end of each of the spray nozzles 182, 184 and 186 from sticking out of the water wall 194. In the case that one end of each of the spray nozzles 182, 184 and 186 sticks out of the water wall 194, the end may act as a growth interface and thus the reaction product may be deposited thereon.

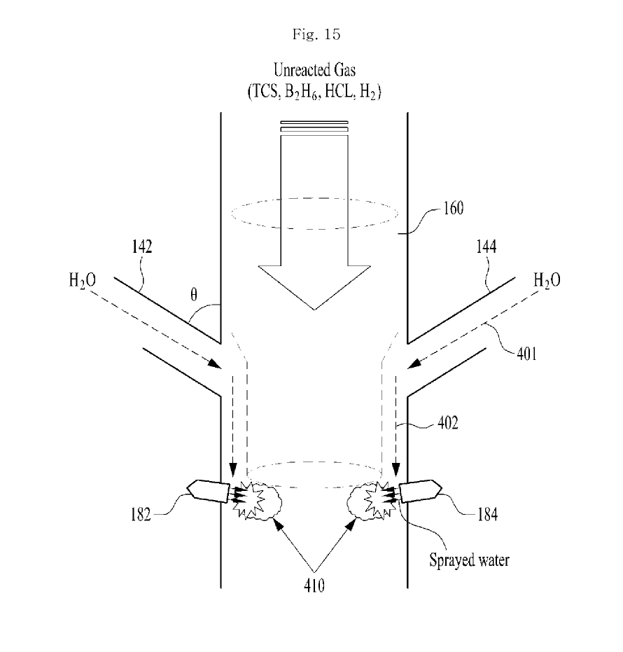

FIG. 15 is a conceptual view illustrating the function of the spray nozzles 182, 184 and 186 shown in FIG. 13.

Referring to FIG. 15, the spray nozzles 182, 184 and 186 may spray, at a predetermined pressure, a gas or a liquid (e.g, deionized water) onto the reaction product 410 deposited on the lower end of the blocking sheet 160 or on the inner wall of the transport duct 108 under the lower end of the blocking sheet 160, thereby separating the reaction product from the lower end of the blocking sheet 160 or the inner wall of the transport duct 108 or dissolving the reaction product.

Through such physical separation or breaking down of the reaction product, the inlet may be prevented from being clogged by the reaction product and may be semi-permanently used. In addition, the reacting system does not need to be stopped for replacement of the inlet, and accordingly the amount of production may increase.

Various embodiments have been described in the best mode for carrying out the invention.

### INDUSTRIAL APPLICABILITY

According to one embodiment, a replacement period of an inlet may be extended, and the time for which the reacting system is stopped for replacement of the inlet may be reduced. Thereby, the amount of production may increase.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

1. An inlet comprising:
a body provided therein with a transport duct allowing a fluid to flow therethrough;
at least one first nozzle connected to one region of a lateral surface of the body and adapted to spray a cleaning solution into the transport duct; and
a blocking sheet disposed in the transport duct to be spaced apart from an inner wall of the transport duct,
wherein the cleaning solution sprayed from the first nozzle is blocked from being introduced into one region of the transport duct positioned inside the blocking sheet.

2. The inlet according to claim 1, wherein an upper end of the blocking sheet is positioned at an upper side of the first nozzle, and a lower end of the blocking sheet is positioned at a lower side of the first nozzle.

3. The inlet according to claim 1, wherein the body is provided with a fixing portion positioned at an upper side of the first nozzle in the transport duct to support an upper end of the blocking sheet.

4. The inlet according to claim 3, wherein the fixing portion is a part of the body positioned at the upper side of the first nozzle,
wherein an inner diameter of the fixing portion is less than an inner diameter of the other part of the body.

5. The inlet according to claim 1, wherein at least one first nozzle includes a plurality of first nozzles arranged spaced apart from each other.

6. The inlet according to claim 1, wherein an angle formed between the first nozzles and an outer wall of the body positioned at an upper side of the first nozzles is between 50° and 70°.

7. The inlet according to claim 1, wherein the blocking sheet is formed of a resin material having a coefficient of friction less than a coefficient of friction of the body.

8. The inlet according to claim 7, wherein the blocking sheet is formed of polytetrafluoroethylene.

9. The inlet according to claim 1, wherein the blocking sheet is provided with an upper end, a lower end, and a lateral surface positioned between the upper end and the lower end, and is formed in a cylindrical shape and open at the upper end of the lower end.

10. The inlet according to claim 9, wherein the upper end of the blocking sheet is formed in a ring shape having a diameter greater than a diameter of the lateral surface to be held by the fixing portion.

11. The inlet according to claim 10, wherein the upper end of the blocking sheet protrudes from the lateral surface.

12. The inlet according to claim 1, further comprising at least one second nozzle connected to another region of the lateral surface of the body positioned under the blocking sheet and adapted to spray an inert gas into the transport duct.

13. The inlet according to claim 12, wherein the at least one second nozzle includes a plurality of second nozzles arranged spaced apart from each other.

14. The inlet according to claim 12, wherein an angle formed between the second nozzles and an outer wall of the body positioned at an upper side of the second nozzles is between 50° and 70°.

15. The inlet according to claim 13, wherein the second nozzles spray the inert gas along an inner wall of the transport duct.

16. The inlet according to claim 12, wherein an angle formed between a direction in which the second nozzle sprays the inert gas and a normal line to an inner wall of the transport duct is greater than 0° and less than 10°.

17. The inlet according to claim 1, further comprising at least one spray nozzle to spray, at a predetermined spray pressure, a gas or a liquid onto a reaction product deposited on a lower end of the blocking sheet or deposited on an inner wall of ht transport duct under the blocking sheet, wherein the reaction product is an output according to reaction between the fluid introduced into the transport duct and the cleaning solution.

18. The inlet according to claim 17, wherein the least one first nozzle and the at least one spray nozzle spray deionized water, the at least one spray nozzle including a plurality of spray nozzles.

19. The inlet according to claim 18, wherein a ratio of a spray pressure of the deionized water sprayed from the first nozzle to a spray pressure of the deionized water sprayed from the spray nozzle is 1:1.5 to 3.

20. A reacting system comprising:
a gas introduction pipe to supply a source gas;
a reactor to form a reaction product using the source gas supplied through the gas introduction pipe;
a gas discharge pipe to discharge a gas produced after formation of the reaction product from the reactor;
a scrubber to clean the gas discharged from the gas discharge pipe using a cleaning solution; and
an inlet to connect the gas discharge pipe to the scrubber, wherein the inlet comprises:
a body provided therein with a transport duct allowing a fluid to flow therethrough;
at least one first nozzle connected to one region of a lateral surface of the body and adapted to spray the cleaning solution into the transport duct; and
a blocking sheet disposed in the transport duct to be spaced apart from an inner wall of the transport duct,
wherein the cleaning solution sprayed from the first nozzle is blocked from being introduced into one region of the transport duct positioned inside the blocking sheet.
